(19) United States
(12) Patent Application Publication
(10) Pub. No.: US 2008/0246642 A1
(43) Pub. Date: Oct. 9, 2008

(54) Digital-to-analog signal converter, and digital-to-analog signal converting method

(75) Inventor: Shawn Min, Yongkang City (TW)

Correspondence Address: GALLAGHER & LATHROP, A PROFESSIONAL CORPORATION, 601 CALIFORNIA ST, SUITE 1111, SAN FRANCISCO, CA, 94108, US

(73) Assignee: Realtek Semiconductor Corp., Hsinchu (TW)

(21) Appl. No.: 12/082,128

(22) Filed: Apr. 8, 2008

(30) Foreign Application Priority Data
Apr. 9, 2007 (TW) 096112321

(51) Int. Cl. H03M 1/66

(52) U.S. Cl. 341/144

(57) ABSTRACT

A digital-to-analog signal converter includes a digital-to-analog signal converting unit adapted for converting a digital video signal into a pair of analog differential current signals by current steering, and a driving unit coupled to the digital-to-analog signal converting unit for converting the analog differential current signals into a driving voltage signal that is adapted for driving a display device. A digital-to-analog signal converting method for driving a display device is also disclosed.

### CROSS-REFERENCE TO RELATED APPLICATION

This application claims priority of Taiwanese application no. 096112321, filed on Apr. 9, 2007.

### BACKGROUND OF THE INVENTION

1. Field of the Invention

The invention relates to a digital-to-analog signal converter, more particularly to a digital-to-analog signal converter suitable for application to a video encoder.

2. Description of the Related Art

Referring to FIG. 1, a conventional video encoder 11 is shown to include an encoding unit 111 and a digital-to-analog (D/A) signal converting unit 112 coupled to the encoding unit 111. The video encoder 11 is used to encode an input digital video signal and to convert the same into an analog video signal that complies with standard video signal specifications and that is supplied to a display device 13 through a wire 12 for driving the display device 13.

The larger the effective bit number of the D/A signal converting unit 112, the better will be the output quality of the video encoder 11. In general, the D/A signal converting unit 112 is realized using current steering techniques, has a clock frequency of 27 MHz, 54 MHz, 108 MHz or 216 MHz, and 8 to 14 effective bits, and employs thermometer-coded signals or binary-coded signals for control. FIG. 2 shows an implementation of the D/A signal converting unit 112 that uses thermometer-coded signals for control.

Referring to FIGS. 1 and 3, the analog video signal includes a luma-chroma (YC) signal and a sync signal. In general, the YC signal ranges between 0 and 0.7 volt, whereas the sync signal ranges between −0.3 and 0 volt. As such, the analog video signal has a dynamic range of 1 volt. When the video encoder 11 outputs the analog video signal in current form, one end of the wire 12 that is coupled to the video encoder 11 is connected to ground via a source end resistor 14, and the other end of the wire 12 is connected to ground via an inherent load end resistor 131 of the display device 13. If each of the source end resistor 14 and the load end resistor 131 has a resistance of 75 ohms, then the video encoder 11 must be able to drive a load of about 37.5 ohms. Since the D/A signal converting unit 112 drives a load directly, it must possess high resolution capability and high driving ability at the same time, thereby resulting in difficulty in designing the D/A signal converting unit 112.

Referring further to FIG. 4, when the video encoder 11 outputs the analog video signal in voltage form, the video encoder 11 is connected to ground through a capacitor 15, a source end resistor 14, a wire 12, and an inherent load end resistor 131 of the display device 13. The video encoder 11 further includes a resistor 113 and a buffer amplifier unit 114. Through the resistor 113 that is connected to the D/A signal converting unit 112, output current from the D/A signal converting unit 112 can be converted into a voltage that is subsequently amplified by the buffer amplifier unit 114 for driving the display device 13.

Since the display device 13 is driven by the buffer amplifier unit 114, the D/A signal converting unit 112 is only required to have high resolution capability, thereby simplifying the design thereof. Moreover, since the video encoder 11 outputs the analog video signal in voltage form, the output current can be reduced so as to reduce the size and power consumption of the video encoder 11.

Referring to FIG. 5, the resistor 113 and the buffer amplifier unit 114 in the video encoder 11 of FIG. 4 may be replaced with a resistor 115 and an amplifier unit 116. The amplifier unit 116 cooperates with the resistor 115 to convert output current from the D/A signal converting unit 112 into a voltage for driving the display device 13. Since the output current from the D/A signal converting unit 112 is converted directly into a voltage for driving the display device 13, both the size and power consumption of the video encoder 11 can be further reduced.

However, the structures of the D/A signal converting units 112 used in the aforementioned conventional video encoders 11 are based on single-ended current steering, which is not suited for high-speed operations and which easily generates surges.

### SUMMARY OF THE INVENTION

Therefore, the main object of the present invention is to provide a digital-to-analog signal converter that is suited for high-speed operations and that is less prone to surge generation.

Another object of the present invention is to provide a digital-to-analog signal converting method that is suited for high-speed operations and that is less prone to surge generation.

According to one aspect of the present invention, there is provided a digital-to-analog signal converter adapted for driving a display device. The digital-to-analog signal converter comprises a digital-to-analog signal converting unit and a driving unit. The digital-to-analog signal converting unit is adapted for converting a digital video signal into a pair of analog differential current signals by current steering. The driving unit is coupled to the digital-to-analog signal converting unit for converting the analog differential current signals into a driving voltage signal that is adapted for driving the display device.

According to another aspect of the present invention, there is provided a digital-to-analog signal converting method for driving a display device. The digital-to-analog signal converting method comprises the steps of: converting a digital video signal into a pair of analog differential current signals by current steering; and converting the analog differential current signals into a driving voltage signal that is adapted for driving the display device.

### BRIEF DESCRIPTION OF THE DRAWINGS

Other features and advantages of the present invention will become apparent in the following detailed description of the preferred embodiments with reference to the accompanying drawings, of which:

FIG. 1 is a schematic circuit block diagram of a conventional video encoder;

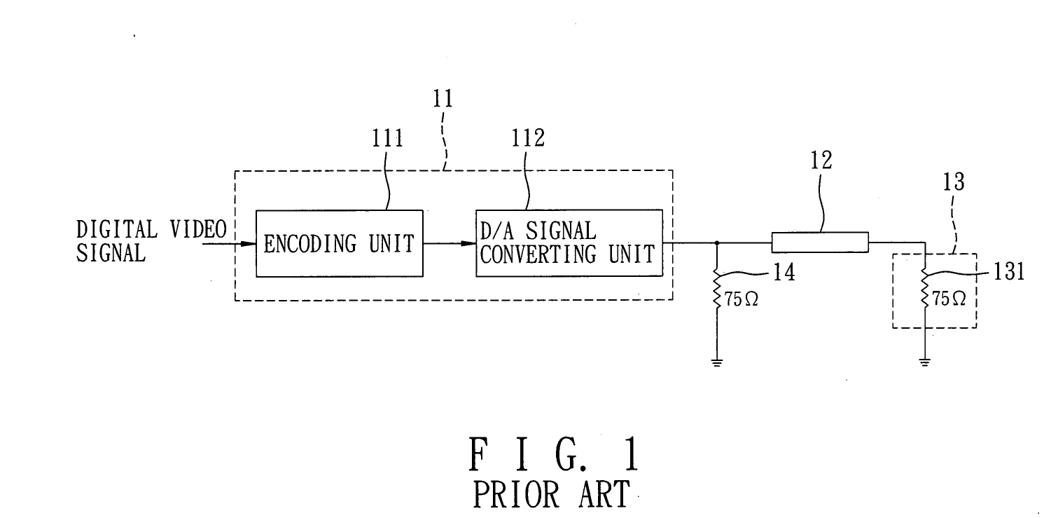

FIG. 2 is a schematic circuit diagram of a conventional single-ended current steering digital-to-analog signal converting unit controllable using thermometer-coded signals;

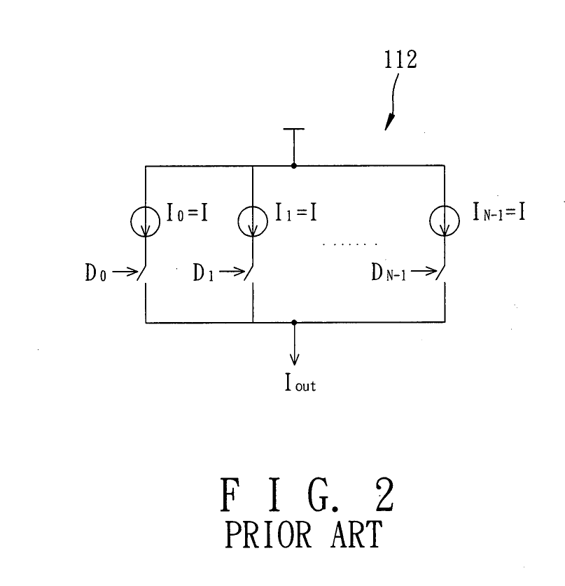

FIG. 3 is a plot to illustrate an analog video signal for driving a display device;

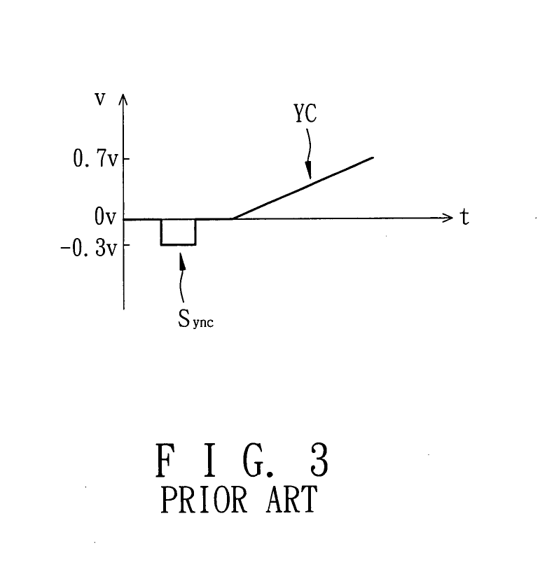

FIG. 4 is a schematic circuit block diagram of another conventional video encoder;

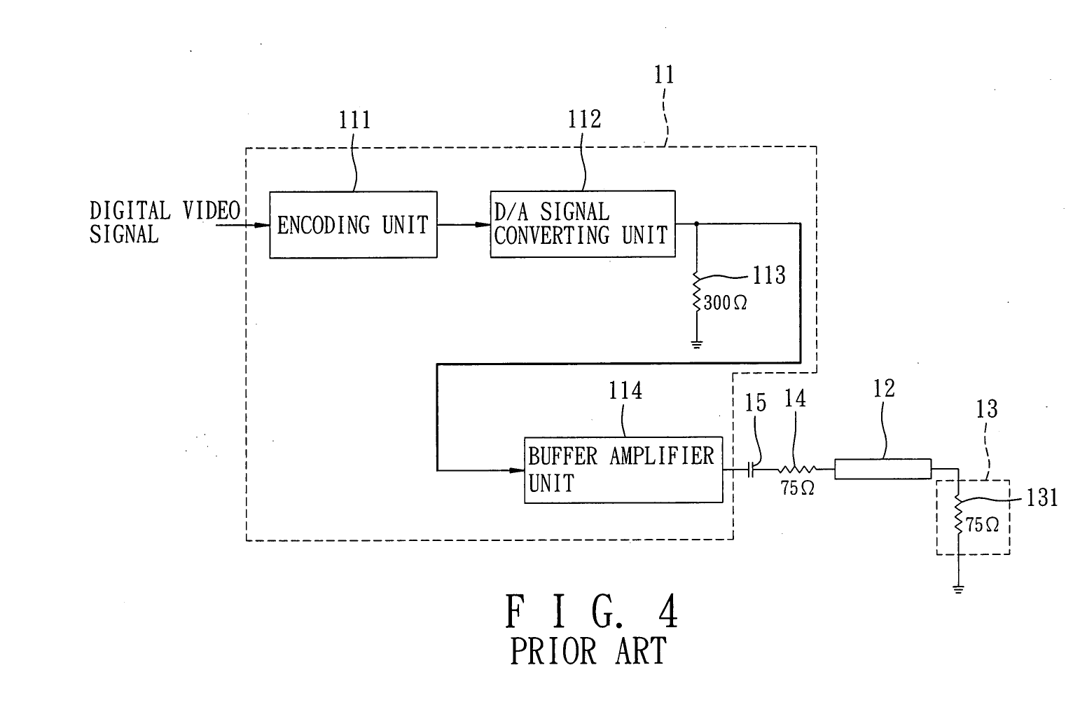

FIG. 5 is a schematic circuit block diagram of yet another conventional video encoder;

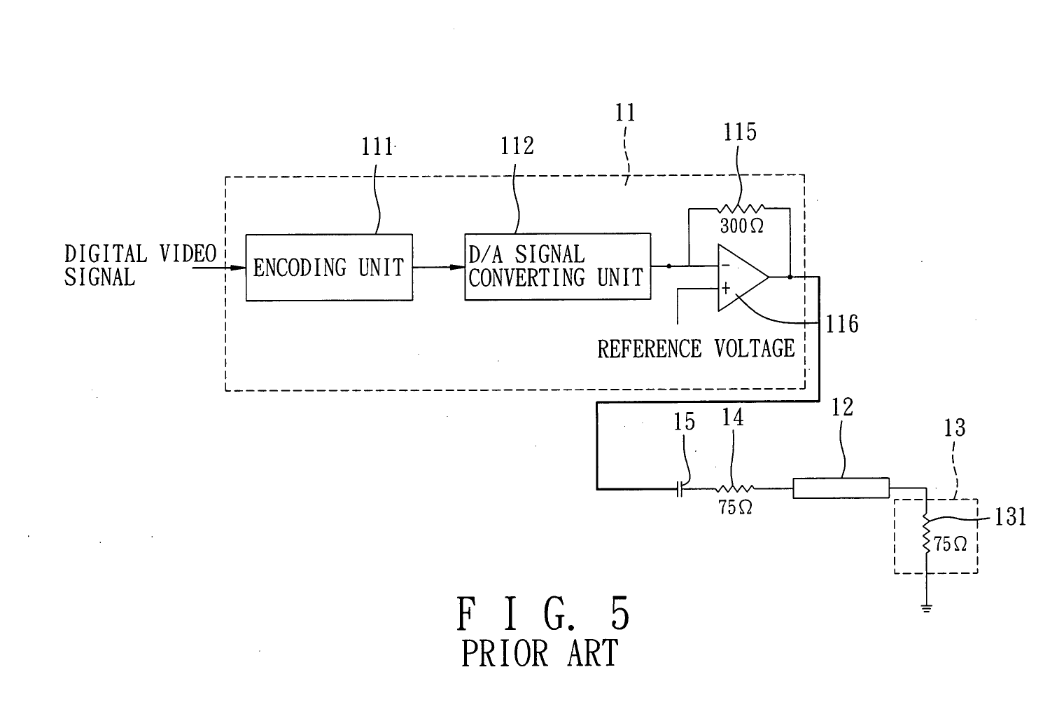

FIG. 6 is a schematic circuit block diagram to illustrate the first preferred embodiment of a digital-to-analog signal converter according to the present invention;

FIG. 7 is a schematic circuit diagram of a differential current steering digital-to-analog signal converting unit controllable using thermometer-coded signals and employed in the first preferred embodiment of this invention;

FIG. 8 is a schematic circuit block diagram to illustrate the second preferred embodiment of a digital-to-analog signal converter according to the present invention;

FIG. 9 is a schematic circuit block diagram to illustrate the third preferred embodiment of a digital-to-analog signal converter according to the present invention; and

FIG. 10 is a schematic circuit block diagram to illustrate the fourth preferred embodiment of a digital-to-analog signal converter according to the present invention.

### DETAILED DESCRIPTION OF THE PREFERRED EMBODIMENTS

Before the present invention is described in greater detail with reference to the accompanying preferred embodiments, it should be noted herein that like elements are denoted by the same reference numerals throughout the disclosure.

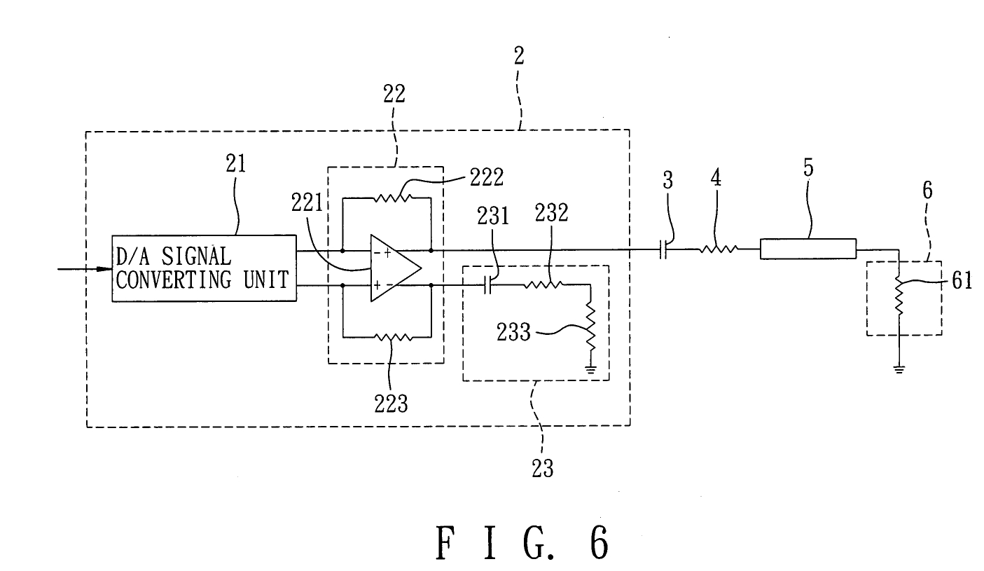

Referring to FIG. 6, the first preferred embodiment of a digital-to-analog (D/A) signal converter 2 according to the present invention is shown to be adapted for driving a display device 6. The D/A signal converter 2 comprises a D/A signal converting unit 21,a driving unit 22, and a load unit 23. The D/A signal converting unit 21 is adapted for converting a digital video signal into a pair of analog differential current signals by current steering. In this embodiment, the driving unit 22 includes an amplifier 221, a first resistor 222, and a second resistor 223. The amplifier 221 has a positive input end, a negative input end, a positive output end, and a negative output end. The positive input end and the negative input end are coupled to the D/A signal converting unit 21. The first resistor 222 is coupled at one end to the negative input end and at another end to the positive output end. The second resistor 223 is coupled at one end to the positive input end and at another end to the negative output end. The amplifier 221 cooperates with the first and second resistors 222, 223 to convert the analog differential current signals into a pair of differential voltage signals for driving the display device 6 and the load unit 23, respectively.

In this embodiment, the analog video signal is outputted in voltage form to drive the display device 6. Therefore, in this embodiment, the positive output end of the amplifier 221 of the driving unit 22 is connected to ground through a capacitor 3, a source end resistor 4, a wire 5, and an inherent load end resistor 61 of the display device 6.

In order for the driving unit 22 to drive balanced loads, i.e., the differential voltage signals from the driving unit 22 drive substantially the same amount of load, the load unit 23 can include a capacitor 231 and a resistor unit connected in series. The resistor unit includes resistors 232,233. The values of the capacitor 231 and the resistors 232, 233 are chosen to correspond to those of the capacitor 3, the source end resistor 4 and the load end resistor 61, respectively. The negative output end of the amplifier 221 of the driving unit 22 is connected to ground through the capacitor 231 and the resistors 232, 233.

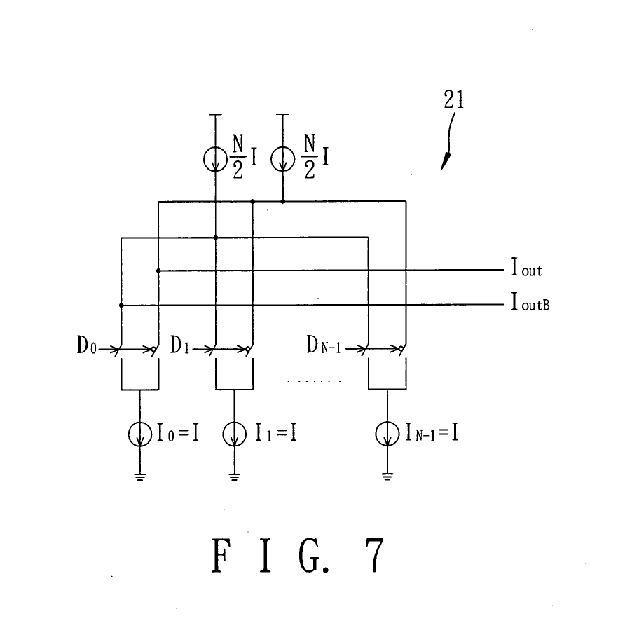

Referring to FIG. 7, the D/A signal converting unit 21 is configured to convert a thermometer-coded digital video signal into the analog differential current signals by current steering. However, the digital video signal may be a binary-coded signal in other embodiments of this invention. Since the feature of the present invention does not reside in the actual design of the D/A signal converting unit 21, which can be readily appreciated by those skilled in the art, further details of the same will be omitted herein for the sake of brevity.

In this embodiment, since the D/A signal converting unit 21 outputs analog differential current signals, it is only required to alter paths of electric currents, and there is no need for change between 0 and a stable value. Therefore, operating speed can be increased, and generation of surges can be reduced.

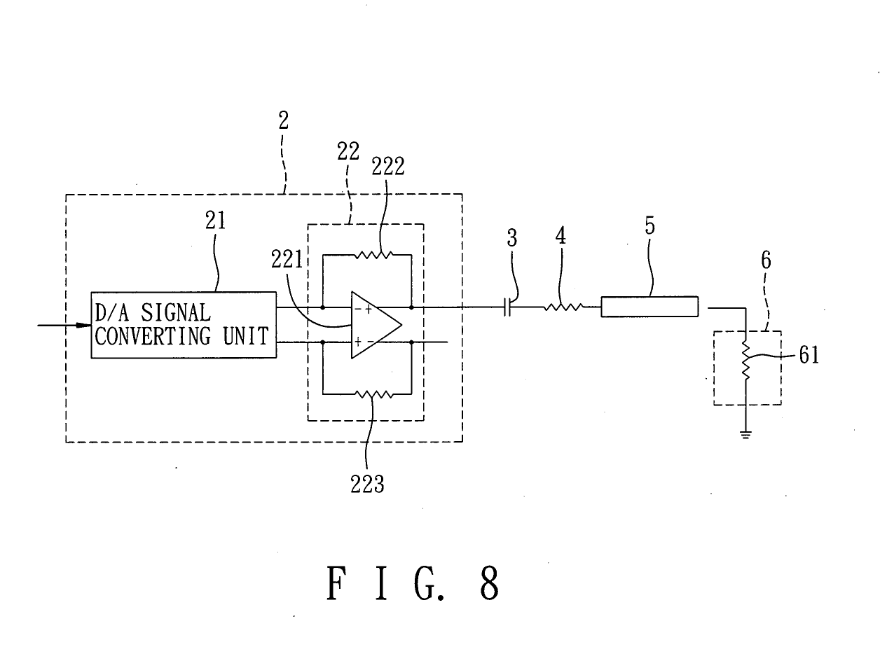

Referring to FIG. 8, in the second preferred embodiment of the present invention, the D/A signal converter 2 does not include the load unit 23 of the first preferred embodiment, and the negative output end of the amplifier 221 of the driving unit 22 is kept floating. Compared to the first preferred embodiment, power consumption in this embodiment can be reduced by about one-half.

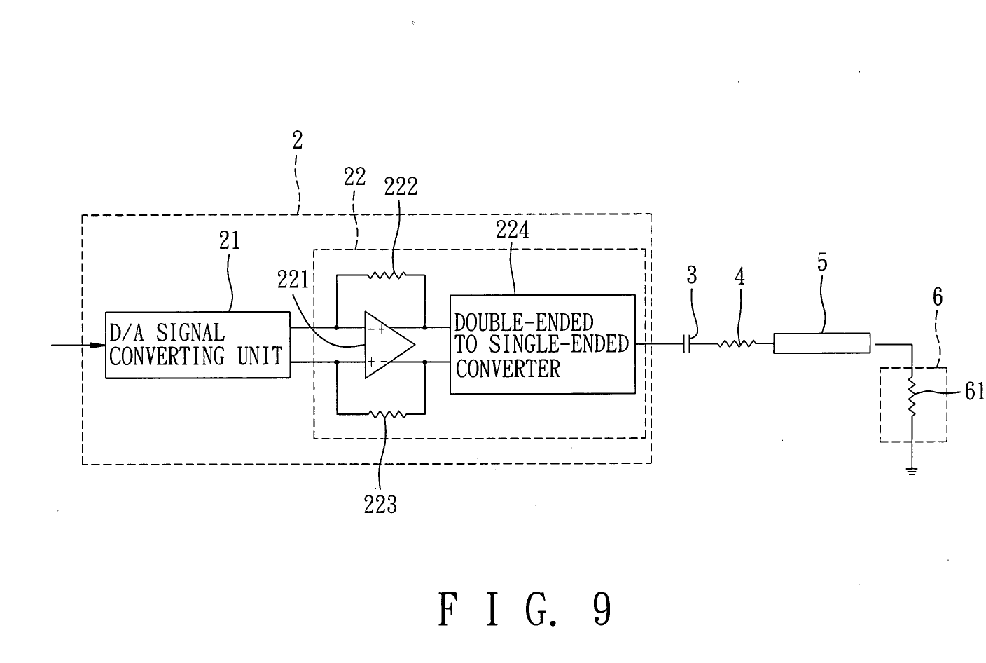

Referring to FIG. 9, the third preferred embodiment of the present invention differs from the second preferred embodiment in that the driving unit 22 of the third preferred embodiment further includes a double-ended to single-ended converter 224 coupled to the positive output end and the negative output end of the amplifier 221 of the driving unit 22 for converting the pair of differential voltage signals into a single-ended voltage signal that is utilized as a driving voltage signal for driving the display device 6. Compared to the first preferred embodiment, power consumption in this embodiment can also be reduced by about one-half.

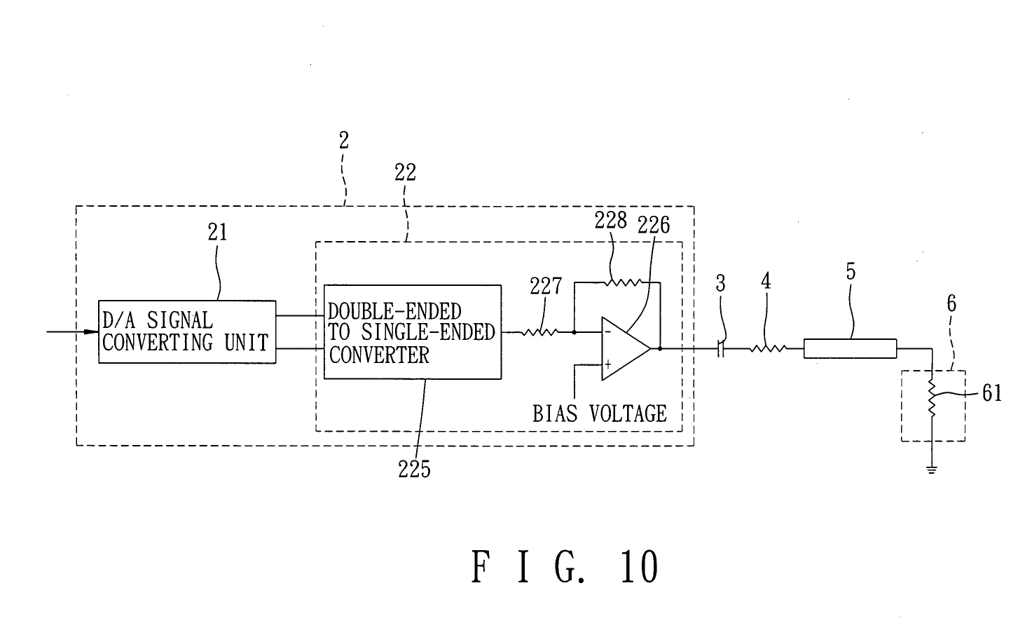

Referring to FIG. 10, the fourth preferred embodiment of the present invention differs from the first preferred embodiment in that the driving unit 22 of the fourth preferred embodiment includes a double-ended to single-ended converter 225, a first resistor 227, an amplifier 226, and a second resistor 228. The double-ended to single-ended converter 225 is coupled to the D/A signal converting unit 21 for converting the pair of analog differential current signals into a single-ended current signal. The first resistor 227 is coupled at one end to the double-ended to single-ended converter 225. The amplifier 226 has a positive input end for receiving a bias voltage, a negative input end coupled to another end of the first resistor 227, and an output end. The second resistor 228 is coupled at one end to the negative input end and at another end to the output end. The amplifier 226 cooperates with the first and second resistors 227, 228 to convert the single-ended current signal into the driving voltage signal for driving the display device 6. Compared to the first preferred embodiment, power consumption in this embodiment can also be reduced by about one-half.

It should be noted that, in practice, the digital video signal inputted into the present invention can be a composite video signal (CVBS), a digital color space signal (YCbCr), or an analog color space signal (YPrPb).

In sum, since the D/A signal converting unit 21 employed in this invention outputs analog differential current signals, operating speed can be increased, and generation of surges can be reduced.

While the present invention has been described in connection with what are considered the most practical and preferred embodiments, it is understood that this invention is not limited to the disclosed embodiments but is intended to cover various arrangements included within the spirit and scope of the broadest interpretation so as to encompass all such modifications and equivalent arrangements.

What is claimed is:

1. A digital-to-analog signal converter adapted for driving a display device, said digital-to-analog signal converter comprising:
a digital-to-analog signal converting unit adapted for converting a digital video signal into a pair of analog differential current signals by current steering; and
a driving unit coupled to said digital-to-analog signal converting unit for converting the analog differential current signals into a driving voltage signal that is adapted for driving the display device.

2. The digital-to-analog signal converter as claimed in claim 1, wherein the digital video signal is one of a thermometer-coded signal and a binary-coded signal.

3. The digital-to-analog signal converter as claimed in claim 1, wherein said driving unit converts the pair of analog differential current signals into a pair of differential voltage signals, and one of the differential voltage signals is utilized as the driving voltage signal.

4. The digital-to-analog signal converter as claimed in claim 3, further comprising a load unit coupled to said driving unit and driven by the other one of the differential voltage signals from said driving unit, said load unit being configured such that the differential voltage signals from said driving unit drive substantially the same amount of load.

5. The digital-to-analog signal converter as claimed in claim 4, wherein said load unit includes a capacitor and a resistor unit connected in series.

6. The digital-to-analog signal converter as claimed in claim 3, wherein said driving unit includes:
an amplifier having a positive input end, a negative input end, a positive output end, and a negative output end, said positive input end and said negative input end being coupled to said digital-to-analog signal converting unit;
a first resistor coupled at one end to said negative input end and at another end to said positive output end; and
a second resistor coupled at one end to said positive input end and at another end to said negative output end.

7. The digital-to-analog signal converter as claimed in claim 6, further comprising a load unit coupled to said driving unit and driven by the other one of the differential voltage signals from said driving unit, said load unit being configured such that the differential voltage signals from said driving unit drive substantially the same amount of load.

8. The digital-to-analog signal converter as claimed in claim 7, wherein said load unit includes a capacitor and a resistor unit connected in series.

9. The digital-to-analog signal converter as claimed in claim 1, wherein said driving unit converts the pair of analog differential current signals into a pair of differential voltage signals, and further converts the pair of differential voltage signals into a single-ended voltage signal that is utilized as the driving voltage signal.

10. The digital-to-analog signal converter as claimed in claim 9, wherein said driving unit includes:
an amplifier having a positive input end, a negative input end, a positive output end, and a negative output end, said positive input end and said negative input end being coupled to said digital-to-analog signal converting unit;
a first resistor coupled at one end to said negative input end and at another end to said positive output end;
a second resistor coupled at one end to said positive input end and at another end to said negative output end;
said amplifier cooperating with said first and second resistors to convert the analog differential current signals into the differential voltage signals; and
a double-ended to single-ended converter coupled to said positive output end and said negative output end of said amplifier for converting the pair of differential voltage signals into the single-ended voltage signal.

11. The digital-to-analog signal converter as claimed in claim 1, wherein said driving unit converts the pair of analog differential current signals into a single-ended current signal, and further converts the single-ended current signal into the driving voltage signal.

12. The digital-to-analog signal converter as claimed in claim 11, wherein said driving unit includes:
a double-ended to single-ended converter coupled to said digital-to-analog signal converting unit for converting the pair of analog differential current signals into the single-ended current signal;
a first resistor coupled at one end to said double-ended to single-ended converter;
an amplifier having a positive input end for receiving a bias voltage, a negative input end coupled to another end of said first resistor, and an output end; and
a second resistor coupled at one end to said negative input end and at another end to said output end;
said amplifier cooperating with said first and second resistors to convert the single-ended current signal into the driving voltage signal.

13. The digital-to-analog signal converter as claimed in claim 1, wherein the digital video signal is one of a composite video signal, a digital color space signal, and an analog color space signal.

14. A digital-to-analog signal converting method for driving a display device, comprising the steps of:
a) converting a digital video signal into a pair of analog differential current signals by current steering; and
b) converting the analog differential current signals into a driving voltage signal that is adapted for driving the display device.

15. The digital-to-analog signal converting method as claimed in claim 14, wherein the digital video signal is one of a thermometer-coded signal and a binary-coded signal.

16. The digital-to-analog signal converting method as claimed in claim 14, wherein, in step b), the analog differential current signals are converted into a pair of differential voltage signals, and one of the differential voltage signals is utilized as the driving voltage signal.

17. The digital-to-analog signal converting method as claimed in claim 16, wherein, in step b), a load unit is driven by the other one of the differential voltage signals and is configured such that the pair of differential voltage signals drive substantially the same amount of load.

18. The digital-to-analog signal converting method as claimed in claim 14, wherein, in step b), the analog differential current signals are converted into a pair of differential voltage signals, which are further converted into a single-ended voltage signal that is utilized as the driving voltage signal.

19. The digital-to-analog signal converting method as claimed in claim 14, wherein, in step b), the analog differential current signals are converted into a single-ended current signal, which is further converted into the driving voltage signal.

20. The digital-to-analog signal converting method as claimed in claim 14, wherein the digital video signal is one of a composite video signal, a digital color space signal, and an analog color space signal.
